(19) United States
(12) Patent Application Publication
(10) Pub. No.: US 2009/0226614 A1
(43) Pub. Date: Sep. 10, 2009

(54) POROUS GAS HEATING DEVICE FOR A VAPOR DEPOSITION SYSTEM

(75) Inventor: Ronald Nasman, Averill Park, NY (US)

Correspondence Address: Tokyo Electron U.S. Holdings, Inc., 4350 West Chandler Blvd., Suite 10/11, Chandler, AZ, 85226, US

(73) Assignee: TOKYO ELECTRON LIMITED, Tokyo (JP)

(21) Appl. No.: 12/042,039

(22) Filed: Mar. 4, 2008

(51) Int. Cl. C23C 16/455

(52) U.S. Cl. 427/255.28; 118/715

(57) ABSTRACT

A method and system for treating a substrate is described. For example, the method and system may be used to deposit a thin film on a substrate using a vapor deposition process. The processing system comprises a gas distribution device for controlling the temperature of a process gas, such as one or more constituents of a film forming composition. The gas distribution device comprises one or more porous gas distribution elements configured to be temperature controlled and distribute a process gas flowing through the one or more porous gas distribution elements. The gas distribution device may be configured to pyrolize the process gas.

### CROSS-REFERENCE TO RELATED APPLICATIONS

This application is related to pending U.S. patent application Ser. No. 11/693,067, entitled “VAPOR DEPOSITION SYSTEM AND METHOD OF OPERATING”, Docket No. TTCA-195, filed on Mar. 29, 2007; and pending U.S. patent application Ser. No. 12/xxx,xxx, entitled “GAS HEATING DEVICE FOR A VAPOR DEPOSITION SYSTEM”, Docket No. TTCA-216, filed on Feb. dd, 2008. The entire content of these applications is herein incorporated by reference in its entirety.

### BACKGROUND OF THE INVENTION

1. Field of Invention

The present invention relates to a method and system for substrate processing, and more particularly to a method and system for distributing a gas during substrate processing.

2. Description of Related Art

During material processing, such as semiconductor device manufacturing for production of integrated circuits (ICs), vapor deposition is a common technique to form thin films, as well as to form conformal thin films over and within complex topography, on a substrate. Vapor deposition processes can include chemical vapor deposition (CVD) and plasma enhanced CVD (PECVD). For example, in semiconductor manufacturing, such vapor deposition processes may be used for gate dielectric film formation in front-end-of-line (FEOL) operations, and low dielectric constant (low-k) or ultra-low-k, porous or non-porous, dielectric film formation and barrier/seed layer formation for metallization in back-end-of-line (BEOL) operations, as well as capacitor dielectric film formation in DRAM production.

In a CVD process, a continuous stream of film precursor vapor is introduced to a process chamber containing a substrate, wherein the composition of the film precursor has the principal atomic or molecular species found in the film to be formed on the substrate. During this continuous process, the precursor vapor is chemisorbed on the surface of the substrate while it thermally decomposes and reacts with or without the presence of an additional gaseous component that assists the reduction of the chemisorbed material, thus, leaving behind the desired film.

In a PECVD process, the CVD process further includes plasma that is utilized to alter or enhance the film deposition mechanism. For instance, plasma excitation can allow film-forming reactions to proceed at temperatures that are significantly lower than those typically required to produce a similar film by thermally excited CVD. In addition, plasma excitation may activate film-forming chemical reactions that are not energetically or kinetically favored in thermal CVD.

Other CVD techniques include hot-filament CVD (otherwise known as hot-wire CVD or pyrolytic CVD). In hot-filament CVD, a film precursor is thermally decomposed by a resistively heated filament, and the resulting fragmented molecules adsorb and react on the surface of the substrate to leave the desired film. Unlike PECVD, hot-filament CVD does not require formation of plasma. However, hot-filament CVD generally suffers from low deposition rate and poor deposition uniformity due to inefficient thermal decomposition and inadequate filament design and flow conditions.

### SUMMARY OF THE INVENTION

The invention relates to a method and system for substrate processing, and more particularly to a method and system for distributing a gas during substrate processing.

The invention further relates to a system for depositing a thin film using chemical vapor deposition (CVD).

The invention further relates to a method and system for depositing a thin film using pyrolytic CVD, wherein a gas distribution device comprising one or more porous gas distribution elements is utilized to pyrolize a film forming composition.

According to one embodiment, a gas distribution device configured to be coupled to a processing system is described. The gas distribution device is configured to heat a process gas, such as one or more constituents of a film forming composition. For example, the system may be used to deposit a thin film on a substrate using a vapor deposition process. The gas distribution device comprises one or more porous gas distribution elements configured to be heated and pyrolize a process gas flowing through the one or more porous gas distribution elements. For example, the one or more porous gas distribution elements may comprise an open-celled foam.

According to another embodiment, a gas distribution device configured to be coupled to a processing system is described. The gas distribution device comprises a temperature control element; and one or more porous gas distribution elements coupled to a temperature control element and configured to be temperature-controlled and distribute a process gas flowing through the one or more porous gas distribution elements, wherein the one or more porous gas distribution elements comprises an open-celled foam.

According to yet another embodiment, a method of depositing a thin film on a substrate is described, the method comprising: coupling a gas heating device to a process chamber, the gas heating device comprising one or more porous gas distribution elements configured to receive an electrical current from one or more power sources; elevating a temperature of the gas heating device by coupling the electrical current from the one or more power sources to the gas heating device; providing a substrate on a substrate holder in the process chamber of a deposition system; providing a film forming composition to a gas distribution system located above the substrate and opposing an upper surface of the substrate; pyrolizing one or more constituents of the film forming composition using the gas heating device; and exposing the substrate to the film forming composition in the process chamber.

### BRIEF DESCRIPTION OF THE DRAWINGS

In the accompanying drawings:

FIG. 1 depicts a schematic view of a deposition system according to an embodiment;

FIG. 2 depicts a schematic view of a gas distribution system according to an embodiment;

FIG. 3A provides a top view of a gas distribution device according to an embodiment;

FIG. 3B provides a cross-sectional view of the gas distribution device depicted in FIG. 3A;

FIG. 4A provides a top view of a gas distribution device according to another embodiment;

FIG. 4B provides a cross-sectional view of the gas distribution device depicted in FIG. 4A;

FIG. 5A provides a top view of a gas distribution device according to another embodiment;

FIG. 5B provides a cross-sectional view of the gas distribution device depicted in FIG. 5A;

FIG. 6 depicts a schematic view of a gas distribution system according to another embodiment;

FIG. 7 depicts a schematic view of a gas distribution system according to another embodiment;

FIG. 8 depicts a schematic view of a gas distribution system according to another embodiment;

FIG. 9 depicts a schematic view of a gas distribution system according to another embodiment; and

FIG. 10 illustrates a method of depositing a film on a substrate according to an embodiment.

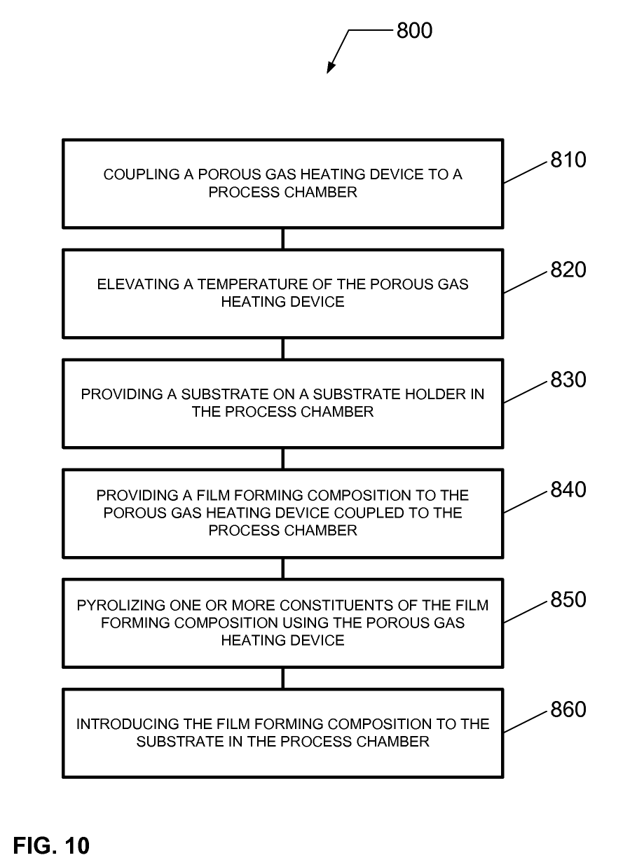

### DETAILED DESCRIPTION OF SEVERAL EMBODIMENTS

In the following description, in order to facilitate a thorough understanding and for purposes of explanation and not limitation, specific details are set forth, such as a particular geometry of the deposition system and descriptions of various components.

However, one skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

In the description and claims, the terms “coupled” and “connected,” along with their derivatives, are used. It should be understood that these terms are not intended as synonyms for each other. Rather, in particular embodiments, “connected” may be used to indicate that two or more elements are in direct physical or electrical contact with each other while “coupled” may further mean that two or more elements are not in direct contact with each other, but yet still co-operate or interact with each other.

Reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

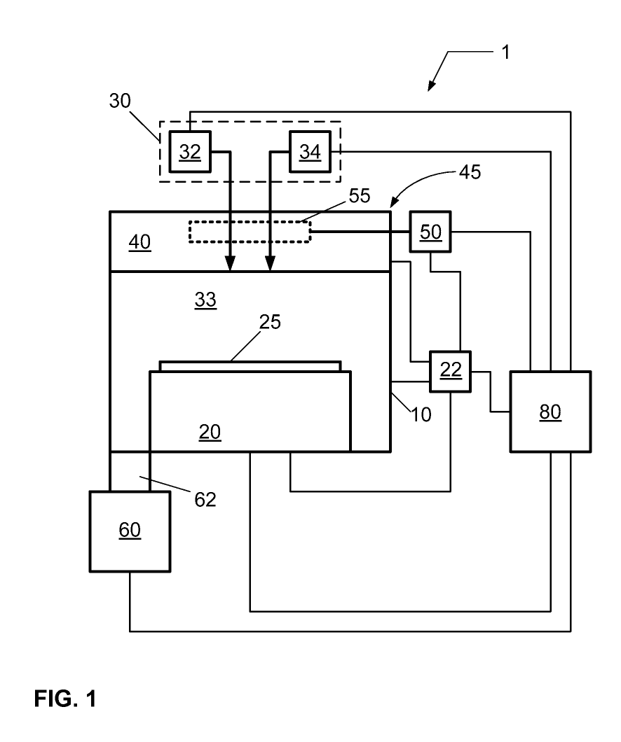

Referring now to the drawings, wherein like reference numerals designate identical or corresponding parts throughout the several views, FIG. 1 schematically illustrates a deposition system 1 for depositing a thin film, such as a conductive film, a non-conductive film, or a semi-conductive film. For example, the thin film can include a dielectric film, such as a low dielectric constant (low-k) or ultra-low-k dielectric film, or the thin film may include a sacrificial layer for use in air gap dielectrics. Deposition system 1 can include a chemical vapor deposition (CVD) system, whereby a film forming composition is thermally activated or decomposed in order to form a film on a substrate. For example, the deposition system 1 comprises a pyrolytic CVD system.

The deposition system 1 comprises a process chamber 10 having a substrate holder 20 configured to support a substrate 25, upon which the thin film is formed. Furthermore, the substrate holder is configured to control the temperature of the substrate at a temperature suitable for the film forming reactions.

The process chamber 10 is coupled to a film forming composition delivery system 30 configured to introduce a film forming composition to the process chamber 10 through a gas distribution system 40. Furthermore, a gas distribution device 45 is coupled to the gas distribution system 40 and configured to chemically modify the film forming composition. The gas distribution device 45 comprises one or more porous gas distribution elements 55 disposed on an interior surface of the gas distribution system 40 or embedded within the gas distribution system 40 or both, and a power source 50 that is coupled to the one or more porous gas distribution elements 55 and that is configured to deliver electrical power to the one or more porous gas distribution elements 55. For example, the one or more porous gas distribution elements 55 can comprise one or more resistively heated porous elements. When electrical current flows through and effects heating of the one or more resistively heated porous elements, the interaction of these heated elements with the film forming composition causes pyrolysis of one or more constituents of the film forming composition.

The process chamber 10 is further coupled to a vacuum pumping system 60 through a duct 62, wherein the vacuum pumping system 60 is configured to evacuate the process chamber 10 and the gas distribution system 40 to a pressure suitable for forming the thin film on the substrate 25 and suitable for pyrolysis of the film forming composition.

The film forming composition delivery system 30 can include one or more material sources configured to introduce a film forming composition to the gas distribution system 40. For example, the film forming composition may include one or more gases, or one or more vapors formed in one or more gases, or a mixture of two or more thereof. The film forming composition delivery system 30 can include one or more gas sources, or one or more vaporization sources, or a combination thereof. Herein vaporization refers to the transformation of a material (normally stored in a state other than a gaseous state) from a non-gaseous state to a gaseous state. Therefore, the terms “vaporization,” “sublimation” and “evaporation” are used interchangeably herein to refer to the general formation of a vapor (gas) from a solid or liquid precursor, regardless of whether the transformation is, for example, from solid to liquid to gas, solid to gas, or liquid to gas.

When the film forming composition is introduced to the gas distribution system 40, one or more constituents of the film forming composition are subjected to pyrolysis by the gas distribution device 45 described above. The film forming composition can include film precursors that may or may not be fragmented by pyrolysis in the gas distribution system 40. The film precursor or precursors may include the principal atomic or molecular species of the film desired to be produced on the substrate. Additionally, the film forming composition can include a reducing agent that may or may not be fragmented by pyrolysis in the gas distribution system 40. The reducing agent or agents may assist with the reduction of a film precursor on substrate 25. For instance, the reducing agent or agents may react with a part of or all of the film precursor on substrate 25. Additionally yet, the film forming composition can include a polymerizing agent (or cross-linker) that may or may not be fragmented by pyrolysis in the gas distribution system 40. The polymerizing agent may assist with the polymerization of a film precursor or fragmented film precursor on substrate 25.

According to one embodiment, when forming a copolymer thin film on substrate 25, a film forming composition comprising two or more monomer gases is introduced to the gas distribution system 40 and is exposed to the gas distribution device 45, i.e., the one or more porous gas distribution elements 55, having a temperature sufficient to pyrolyze one or more of the monomers and produce a source of reactive species. These reactive species are introduced to and distributed within process space 33 in the vicinity of the upper surface of substrate 25. Substrate 25 is maintained at a temperature lower than that of the gas distribution device 45 in order to condensate and induce polymerization of the chemically altered film forming composition at the upper surface of substrate 25.

For example, when forming an organosilicon polymer, monomer gas(es) of an organosilicon precursor is used. Additionally, for example, when forming a fluorocarbon-organosilicon copolymer, monomer gases of a fluorocarbon precursor and organosilicon precursor are used.

Further yet, the film forming composition can include an initiator that may or may not be fragmented by pyrolysis in the gas distribution system 40. An initiator or fragmented initiator may assist with the fragmentation of a film precursor, or the polymerization of a film precursor. The use of an initiator can permit higher deposition rates at lower heat source temperatures. For instance, the one or more heating elements can be used to fragment the initiator to produce radical species of the initiator (i.e., a fragmented initiator) that are reactive with one or more of the remaining constituents in the film forming composition. Furthermore, for instance, the fragmented intiator or initiator radicals can catalyze the formation of radicals of the film forming composition.

For example, when forming a fluorocarbon-organosilicon copolymer, the initiator can be perfluorooctane sulfonyl fluoride (PFOSF) used in the polymerization of a cyclic vinylmethylsiloxane, such as 1,3,5-trivinyl-1,3,5-trimethylcyclotrisiloxane (V₃D₃).

Additionally, for example, when forming a porous SiCOH-containing film, the film forming composition may comprise a structure-forming material and a pore-generating material. The structure-forming material may comprise diethoxymethylsilane (DEMS) and the pore-generating material may comprise alpha-terpinene (ATRP). The porous SiCOH-containing film may be used as a low dielectric constant (low-k) material.

Further, for example, when forming a cross-linked neopentyl methacrylate organic glass, the film forming composition may comprise a monomer, a cross-linker, and an initiator. The monomer may comprise trimethylsilylmethyl methacrylate (TMMA), propargyl methacrylate (PMA), cyclopentyl methacrylate (CPMA), neopentyl methacrylate (npMA), and poly (neopentyl methacrylate) (P(npMA)), and the cross-linker may comprise ethylene glycol diacrylate (EGDA), ethylene glycol dimethacrylate (EGDMA), 1,3-propanediol diacrylate (PDDA), or 1,3-propanediol dimethacrylate (PDDMA), or any combination of two or more thereof. Additionally, the initiator may comprise a peroxide, a hydroperoxide, or a diazine. Additionally yet, the initiator may comprise a tert-butyl peroxide (TBPO).

Further yet, for example, the polymer film may comprise P(npMA-co-EGDA) (poly(neopentyl methacrylate-co-ethylene glycol diacrylate)), and the monomer comprises npMA (neopentyl methacrylate) and the cross-linker comprises EGDA (ethylene glycol diacrylate). The polymer film may be used as a sacrificial air gap material.

According to one embodiment, the film forming composition delivery system 30 can include a first material source 32 configured to introduce one or more film precursors to the gas distribution system 40, and a second material source 34 configured to introduce a (chemical) initiator to the gas distribution system 40. Furthermore, the film forming gas delivery system 30 can include additional gas sources configured to introduce an inert gas, a carrier gas or a dilution gas. For example, the inert gas, carrier gas or dilution gas can include a noble gas, i.e., He, Ne, Ar, Kr, Xe, or Rn.

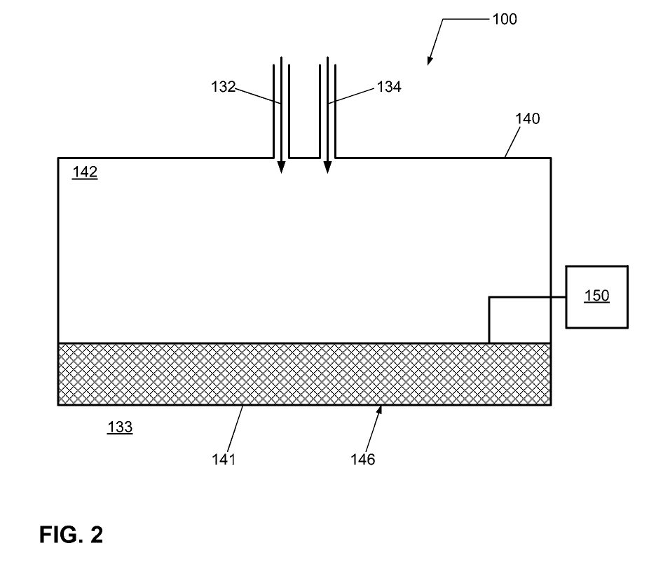

Referring now to FIG. 2, a gas distribution system 100 is illustrated according to an embodiment. The gas distribution system 100 comprises a housing 140 configured to be coupled to or within a process chamber of a processing system (such as process chamber 10 of deposition system 1 in FIG. 1), and a gas distribution device 141 configured to be coupled to the housing 140, wherein the combination form a plenum 142. The gas distribution system 100 may be thermally insulated from the process chamber, or it may not be thermally insulated from the process chamber.

The gas distribution system 100 is configured to receive a process gas or mixture of process gases, such as a film forming composition, into the plenum 142 from a process gas delivery system, such as a film forming composition delivery system (not shown), and distribute the process gas to a process space 133 in the process chamber through an outlet 146 of the gas distribution device 141. For example, the gas distribution system 100 can be configured to receive one or more constituents of a film forming composition 132 and an optional initiator 134 into plenum 142 from the film forming composition delivery system. The one or more constituents of the film forming composition 132 and the optional initiator 134 may be introduced to plenum 142 separately as shown, or they may be introduced through the same opening.

The gas distribution device 141 comprises one or more porous gas distribution elements configured to receive an electrical current from one or more power sources 150 and heat the process gas flowing through the one or more porous gas distribution elements. For example, the one or more porous gas distribution elements may comprise a porous gas distribution plate as illustrated in FIG. 2. However, the one or more porous gas distribution elements may be distributed in order to tailor the spatial distribution of the temperature and/or chemical composition of the process gas flowing through the porous gas distribution device.

According to an embodiment, the gas distribution device 141 can include an open-celled foam. For example, the open-celled foam may comprise a metal-containing foam, a metal foam, or a metal alloy foam. Additionally, for example, the open-celled foam may comprise a non-metal foam. Additionally yet, for example, the open-celled foam may comprise a ceramic foam. Further, the open-celled foam may or may not further include a protective surface coating. Further yet, the open-celled foam may comprise a non-metal foam coated with metal-containing material. When a coating is applied, open-celled foams may be coated using a vapor deposition process, such as physical vapor deposition (PVD) or sputter deposition, or chemical vapor deposition (CVD), or PVD-like or CVD-like deposition processes, or plating, or a combination thereof.

As an example, the open-celled foam may include Duocel® Foam that is commercially available from ERG Materials and Aerospace Corporation (900 Stanford Avenue, Oakland, Calif. 94608). A wide range of materials are commercially offered by ERG Materials and Aerospace Corporation including, but not limited to, aluminum, copper, tin, zinc, nickel, Inconel, silicon, silver, gold, silicon carbide, silicon nitride, silicon nitride carbide, boron carbide, boron nitride, hafnium carbide, tantalum carbide, and zirconium carbide. Various materials may be vapor deposited onto an existing open-celled foam including, for example, sputter-deposited tungsten.

Additionally, the open-celled foam may be fabricated to have a specific foam density, pore size, or ligament structure. For example, the foam density can range from approximately 3% to approximately 60% of the density of the solid base material. In a non-limiting embodiment, a foam density of approximately 15% to approximately 50% and, desirably, approximately 20% to approximately 40%, is used. Additionally, for example, the pore size can range from approximately 5 pores to approximately 60 pores per linear inch. In a non-limiting embodiment, a pore size of approximately 25 pores to approximately 55 pores per linear inch and, desirably, approximately 30 pores to approximately 50 pores per linear inch, is used.

As shown in FIG. 2, the one or more power sources 150 may be configured to couple electrical current directly to the gas distribution device 141. For example, electrical power from the one or more power source 150 may be directly coupled to the one or more porous gas distribution elements. Additionally, for example, electrical power from the one or more power source 150 may be directly to the open-celled foam via direct physical connection of electrical leads to the open-celled foam. Electrical contact may, for instance, be facilitated by various techniques, including soldering, welding, brazing, etc.

The one or more power sources 150 may include a direct current (DC) power source, or they may include an alternating current (AC) power source, or combination thereof. For instance, when the one or more power sources 150 couple electrical power to the gas distribution device 141, the porous gas distribution device may be elevated to a temperature sufficient to pyrolize one or more constituents of the film forming composition.

According to another embodiment, the gas distribution device 141 can include an open-celled foam, and one or more electrodes coupled to the open-celled foam, wherein at least one of the one or more electrodes is coupled to the power source, and wherein at least one of the one or more electrodes is coupled to electrical ground for the power source.

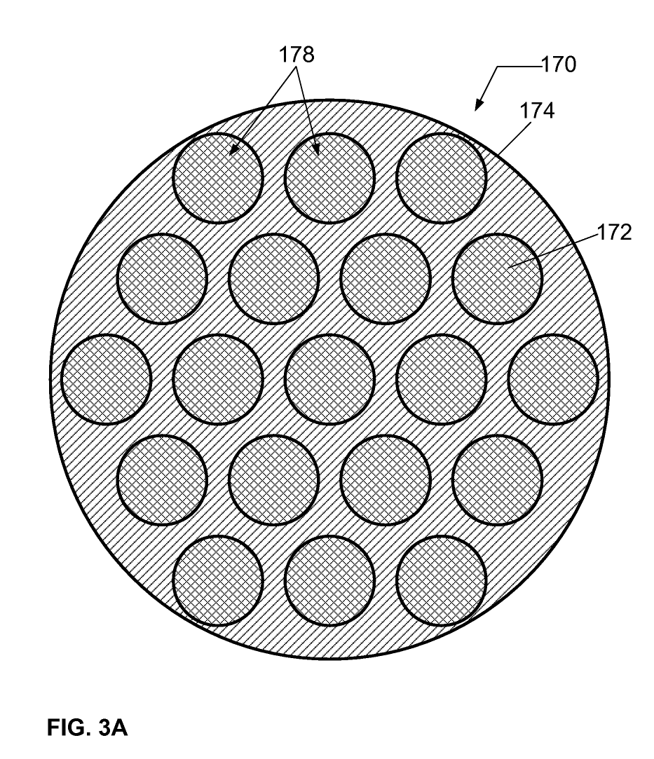

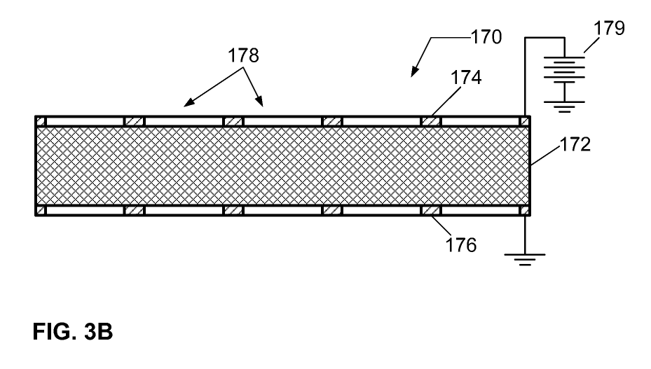

For example, as shown in FIGS. 3A and 3B, a top view and a cross-sectional view of a gas distribution device 170 is presented, respectively. The gas distribution device 170 may be configured to be coupled to the housing 140 shown in FIG. 1. The gas distribution device 170 comprises an open-celled foam 172 disposed between a first electrode 174 located at a top surface of the open-celled foam 172 and a second electrode 176 located at a bottom surface of the open-celled foam 172. A voltage difference can be applied by a power source 179 across the first electrode 174 and the second electrode 176 to cause a flow of electrical current through the open-celled foam 172. The flow of electrical current through the open-celled foam 172 may, in turn, cause heating via Joule (ohmic) heating.

Joule heating refers to the increase in temperature of a conductor as a result of the resistance to a flow of electrical current. The resistance of the conductor is related to the resistivity of the conductor and various geometric parameters, such as the length of the conductor and a cross-sectional dimension of the conductor. At the atomic level, Joule heating is the result of moving electrons colliding with atoms of the conductor, where upon momentum is transferred to the atom thereby increasing its kinetic energy and thus producing heat. Joule's Law is expressed as Q=I²Rt, where Q represents the heat generated by a constant current I flowing through a conductor of resistance R for a time period t.

As illustrated in FIGS. 3A and 3B, the first electrode 174 and the second electrode 176 may span substantially the entire area of the top and bottom surfaces, respectively, of the open-celled foam 172 in order to subject each region of the open-celled foam 172 to about the same voltage difference and, thus, distribute the current flow through the open-celled foam 172. Openings 178 on the first electrode 174 and the second electrode 176 permit the flow of process gas through the gas distribution device 170.

The openings 178 can be distributed in various density patterns on the first electrode 176 and the second electrode 178. For example, openings 178 in the first electrode 174 and the second electrode 176 may or may not be aligned. Additionally, for example, more openings can be formed near the center of the first electrode 174 and the second electrode 176 and less openings can be formed near the periphery of the first electrode 174 and the second electrode 176. Alternatively, for example, more openings can be formed near the periphery of the first electrode 174 and the second electrode 176 and less openings can be formed near the center of the first electrode 174 and the second electrode 176. Additionally yet, the size of the openings can vary on the first electrode 174 and the second electrode 176. For example, larger openings can be formed near the center of the first electrode 174 and the second electrode 176 and smaller openings can be formed near the periphery of the first electrode 174 and the second electrode 176. Alternatively, for example, smaller openings can be formed near the periphery of the first electrode 174 and the second electrode 176 and larger openings can be formed near the center of the first electrode 174 and the second electrode 176. Further yet, the shape of the openings 178 may vary.

According to another embodiment, the gas distribution device 141 can include an open-celled foam, and a resistive heating element coupled to the open-celled foam and configured to heat the open-celled foam when electrical current from the one or more power sources flows through the resistive heating element.

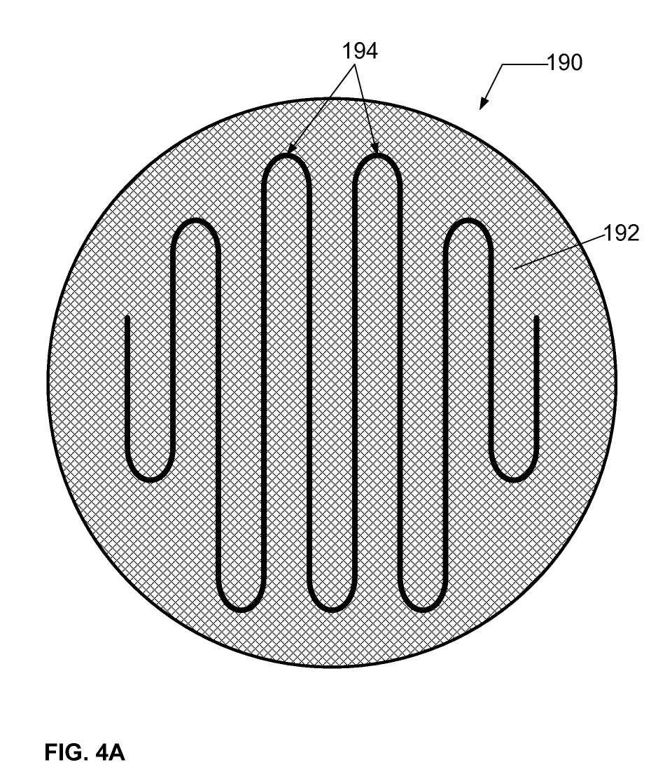

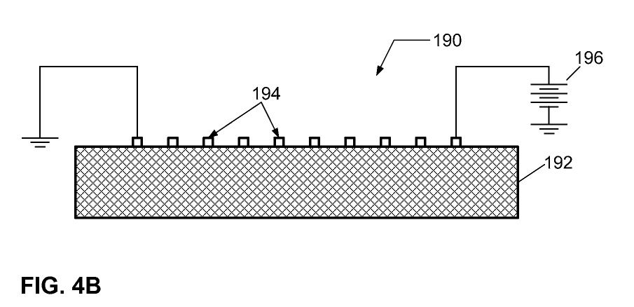

For example, as shown in FIGS. 4A and 4B, a top view and a cross-sectional view of a gas distribution device 190 is presented, respectively. The gas distribution device 190 may be configured to be coupled to the housing 140 shown in FIG. 1. The gas distribution device 190 comprises an open-celled foam 192, and a resistive heating element 194 coupled to a top surface of the open-celled foam 192. Alternatively, the resistive heating element 194 may be coupled to a bottom surface of the open-celled foam 192, or it may be embedded with the open-celled foam 192.

A voltage difference can be applied by a power source 196 between a first end of the resistive heating element 194 and a second of the resistive heating element 194 to cause a flow of electrical current through the resistive heating element 194. The flow of electrical current through the resistive heating element 194 may, in turn, cause heating via Joule (ohmic) heating. This heating may elevate the temperature of the open-celled foam 192. The resistive heating element 194 may be formed in a serpentine-like path as shown in FIG. 4A, or a spiral-like path, or any arbitrary shape. Further, the resistive heating element 194 may or may not be electrically insulated from the open-celled foam 192 depending, for example, on the material/electrical properties of the open-celled foam 192.

Although one resistive heating element 194 is shown in FIGS. 4A and 4B, a plurality of heating elements may be utilized. The heating elements may be distributed in order to tailor the spatial distribution of the temperature and/or chemical composition of the process gas flowing through the porous gas distribution device.

According to yet another embodiment, the gas distribution device 141 can include an open-celled foam, and one or more temperature control elements coupled to the open-celled foam.

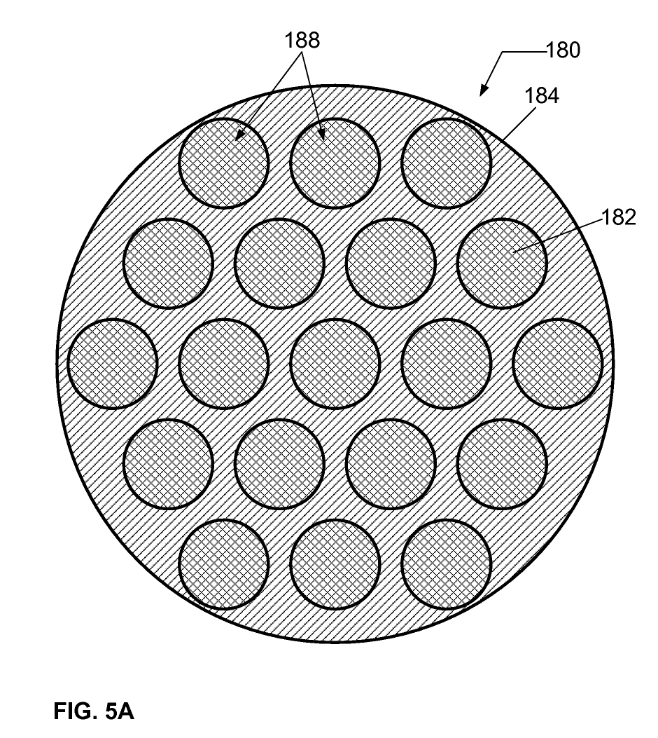

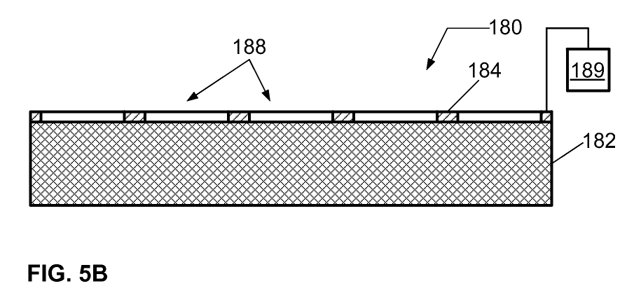

For example, as shown in FIGS. 5A and 5B, a top view and a cross-sectional view of a gas distribution device 180 is presented, respectively. The gas distribution device 180 may be configured to be coupled to the housing 140 shown in FIG. 1. The gas distribution device 180 comprises an open-celled foam 182 coupled to a temperature control element 184 located at a top surface of the open-celled foam 182, as shown in FIG. 5A, or a bottom surface of the open-celled foam 182, or both. As shown in FIG. 5B, a temperature of the temperature control element 184 can be controlled by a temperature control system 189.

The temperature control element 184 may be heated or cooled in order to increase or decrease, respectively, a temperature of the open-celled foam 182. The open-celled foam 182 can be in thermal contact with the temperature control element 184. For example, the open-celled foam 182 may be coupled to the temperature control element 184 via a weld joint, or one or more fasteners, etc.

The temperature control element 184 may include one or more resistive heating elements, or one or more thermoelectric devices, or any combination thereof. The temperature control element 184 may include one or more fluid channels configured to flow a heated or cooled heat transfer fluid through the temperature control element 184.

As illustrated in FIGS. 5A and 5B, the temperature control element 184 may span substantially the entire area of the top and/or bottom surfaces of the open-celled foam 182 in order to subject each region of the open-celled foam 182 to about the same temperature. Openings 188 on the temperature control element 184 permit the flow of process gas through the gas distribution device 180.

The openings 188 can be distributed in various density patterns on the temperature control element 184. For example, openings can be formed near the center of the temperature control element 184 and less openings can be formed near the periphery of the temperature control element 184. Alternatively, for example, more openings can be formed near the periphery of the temperature control element 184 and less openings can be formed near the center of the temperature control element 184. Additionally yet, the size of the openings can vary on the temperature control element 184. For example, larger openings can be formed near the center of the temperature control element 184 and smaller openings can be formed near the periphery of the temperature control element 184. Alternatively, for example, smaller openings can be formed near the periphery of the temperature control element 184 and larger openings can be formed near the center of the temperature control element 184. Further yet, the shape of the openings 188 may vary.

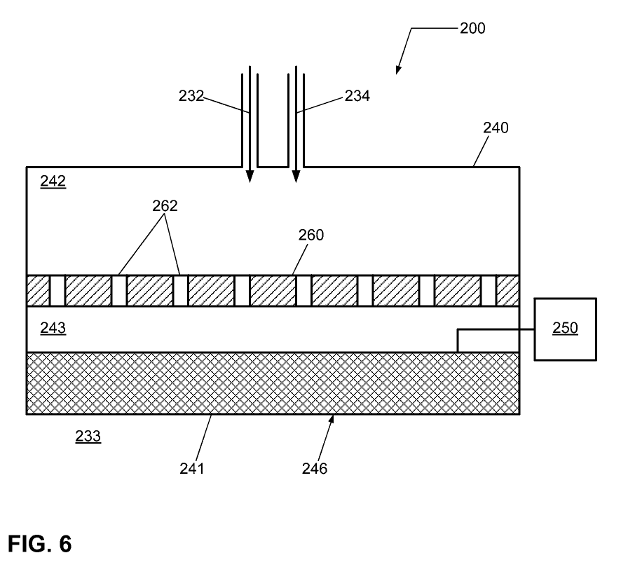

Referring now to FIG. 6, a gas distribution system 200 is illustrated according to another embodiment. The gas distribution system 200 comprises a housing 240 configured to be coupled to or within a process chamber of a processing system (such as process chamber 10 of deposition system 1 in FIG. 1), and a gas distribution device 241 configured to be coupled to the housing 240. The gas distribution system 200 may be thermally insulated from the process chamber, or it may not be thermally insulated from the process chamber.

Additionally, gas distribution system 200 comprises an intermediate gas distribution plate 260 coupled to housing 240 such that the combination of housing 240, intermediate gas distribution plate 260 and gas distribution device 241 form a plenum 242 above intermediate gas distribution plate 260 and an intermediate plenum 243 between the intermediate gas distribution plate 260 and the gas distribution device 241, as shown in FIG. 6. The intermediate gas distribution plate 260 comprises a plurality of openings 262 arranged to distribute and introduce the film forming composition to the intermediate plenum 243.

The gas distribution system 200 is configured to receive a process gas or mixture of process gases, such as a film forming composition, into the plenum 242 from a process gas delivery system, such as a film forming composition delivery system (not shown), and distribute the process gas to a process space 233 in the process chamber through an outlet 246 of the gas distribution device 241. For example, the gas distribution system 200 can be configured to receive one or more constituents of a film forming composition 232 and an optional initiator 234 into plenum 242 from the film forming composition delivery system. The one or more constituents of the film forming composition 232 and the optional initiator 234 may be introduced to plenum 242 separately as shown, or they may be introduced through the same opening.

The gas distribution device 241 comprises one or more porous gas distribution elements configured to receive an electrical current from one or more power sources 250 and heat the process gas flowing through the one or more porous gas distribution elements. For example, the one or more porous gas distribution elements may comprise a porous gas distribution plate as illustrated in FIG. 6. However, the one or more porous gas distribution elements may be distributed in order to tailor the spatial distribution of the temperature and/or chemical composition of the process gas flowing through the porous gas distribution device.

According to an embodiment, the gas distribution device 241 can include an open-celled foam. Further, the open-celled foam may be heated using any one of the techniques described above.

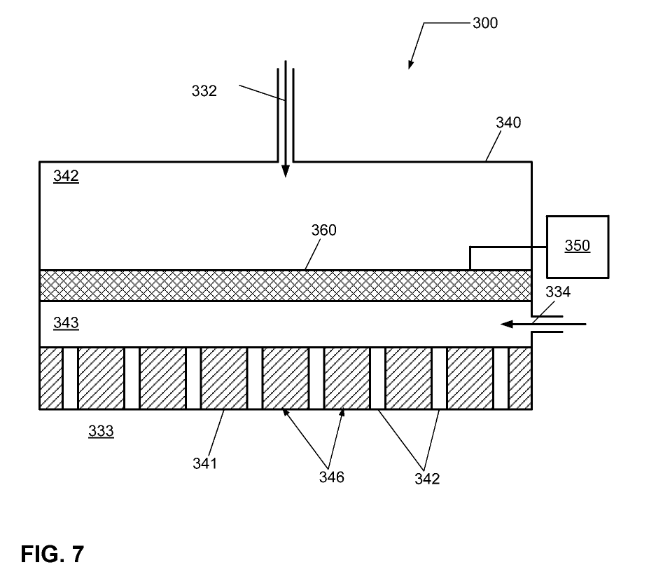

Referring now to FIG. 7, a gas distribution system 300 is illustrated according to another embodiment. The gas distribution system 300 comprises a housing 340 configured to be coupled to or within a process chamber of a processing system (such as process chamber 10 of deposition system 1 in FIG. 1), and a gas distribution plate 341 configured to be coupled to the housing 340. The gas distribution system 300 may be thermally insulated from the process chamber, or it may not be thermally insulated from the process chamber.

Additionally, gas distribution system 300 comprises a gas distribution device 360 coupled to housing 340 such that the combination of housing 340, gas distribution device 360 and gas distribution plate 341 form a plenum 342 above gas distribution device 360 and an intermediate plenum 343 between the gas distribution device 360 and the gas distribution plate 341, as shown in FIG. 7.

The gas distribution system 300 is configured to receive a process gas or mixture of process gases, such as a film forming composition, into the plenum 342 from a process gas delivery system, such as a film forming composition delivery system (not shown), and distribute the process gas to a process space 333 in the process chamber through an outlet 346 of the gas distribution plate 341. For example, the gas distribution system 300 can be configured to receive a first flow 332 of one or more constituents of a film forming composition or an initiator into plenum 342 from the film forming composition delivery system. Additionally, for example, the gas distribution system 300 can be configured to receive a second flow 334 of one or more constituents of a film forming composition or an initiator into intermediate plenum 343 from the film forming composition delivery system. Any constituent of the film forming composition or the initiator or both may be introduced directly to the intermediate plenum 343 in order to avoid or reduce interaction with the gas distribution device 360. For example, the initiator may be introduced to plenum 342 in order to interact with the gas distribution device 360 and undergo pyrolysis, while the remaining constituents of the film forming composition may be introduced to the intermediate plenum 343.

The gas distribution device 360 comprises one or more porous gas distribution elements configured to receive an electrical current from one or more power sources 350 and heat the process gas flowing through the one or more porous gas distribution elements. For example, the one or more porous gas distribution elements may comprise a porous gas distribution plate as illustrated in FIG. 7. However, the one or more porous gas distribution elements may be distributed in order to tailor the spatial distribution of the temperature and/or chemical composition of the process gas flowing through the porous gas distribution device.

According to an embodiment, the gas distribution device 360 can include an open-celled foam. Further, the open-celled foam may be heated using any one of the techniques described above.

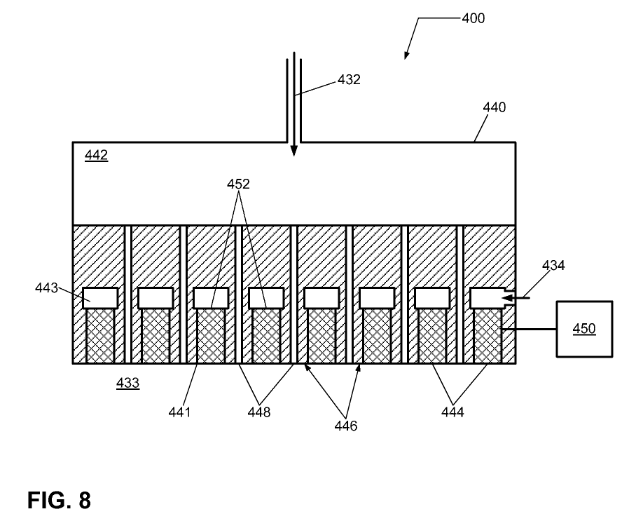

Referring now to FIG. 8, a gas distribution system 400 is illustrated according to another embodiment. The gas distribution system 400 comprises a housing 440 configured to be coupled to or within a process chamber of a processing system (such as process chamber 10 of deposition system 1 in FIG. 1), and a multi-component gas distribution plate 441 configured to be coupled to the housing 440. The gas distribution system 400 is configured to receive a process gas and distribute the process gas to a process space 433 in the process chamber through an outlet 446. The gas distribution system 400 may be thermally insulated from the process chamber, or it may not be thermally insulated from the process chamber.

The multi-component gas distribution plate 441 is configured to independently couple a first composition 432 from a first plenum 442 through a first array of openings 448 to the process space 433 and a second composition 434 from a second plenum 443 through a gas distribution device 444 comprising a second array of porous gas distribution elements 452 to the process space 433 without mixing the first composition 432 and the second composition 434 prior to the process space 433. The first array of openings 448 and the second array of porous gas distribution elements 452 can be arranged, distributed or sized as described above.

The gas distribution device 444 comprises porous gas distribution elements configured to receive an electrical current from one or more power sources 450 and heat the process gas flowing through the one or more porous gas distribution elements. For example, the one or more porous gas distribution elements may comprise a porous gas distribution cylinder or annular ring as illustrated in FIG. 8. However, the one or more porous gas distribution elements may be distributed in order to tailor the spatial distribution of the temperature and/or chemical composition of the process gas flowing through the porous gas distribution device.

According to an embodiment, the gas distribution device 444 can include an open-celled foam. Further, the open-celled foam may be heated using any one of the techniques described above.

The first composition 432 can include one or more constituents of the film forming composition wherein interaction with the gas distribution device 444 is not desired. Additionally, the second composition 434 can include one or more constituents of the film forming composition wherein interaction with the gas distribution device 444 is desired. For example, the first composition 432 can include one or more film forming gases and the second composition 434 can include an initiator. While the one or more film forming gases are introduced to process space 433, the initiator undergoes pyrolysis prior to introduction to process space 433. Once the one or more film forming gases and the initiator radicals interact in process space 433, the initiator radicals can catalyze the dissociation of at least one constituent of the one or more film forming gases.

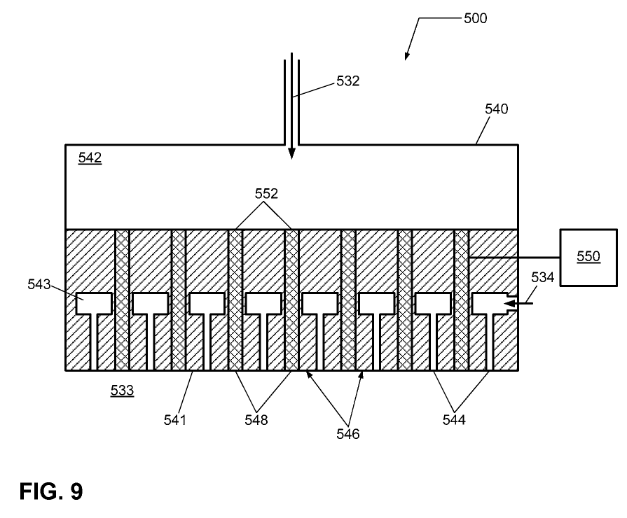

Referring now to FIG. 9, a gas distribution system 500 is illustrated according to yet another embodiment. The gas distribution system 500 comprises a housing 540 configured to be coupled to or within a process chamber of a processing system (such as process chamber 10 of deposition system 1 in FIG. 1), and a multi-component gas distribution plate 541 configured to be coupled to the housing 540. The gas distribution system 500 is configured to receive a process gas and distribute the process gas to a process space 533 in the process chamber through an outlet 546. The gas distribution system 500 may be thermally insulated from the process chamber, or it may not be thermally insulated from the process chamber.

The multi-component gas distribution plate 541 is configured to independently couple a first composition 532 from a first plenum 542 through a gas distribution device 548 comprising a first array of porous gas distribution elements 552 to the process space 533 and a second composition 534 from a second plenum 543 through a second array of openings 544 to the process space 533 without mixing the first composition 532 and the second composition 534 prior to the process space 533. The first array of porous gas distribution elements 552 and the second array of openings 544 and can be arranged, distributed or sized as described above.

The gas distribution device 548 comprises porous gas distribution elements configured to receive an electrical current from one or more power sources 550 and heat the process gas flowing through the one or more porous gas distribution elements. For example, the one or more porous gas distribution elements may comprise a porous gas distribution cylinder or annular ring as illustrated in FIG. 9. However, the one or more porous gas distribution elements may be distributed in order to tailor the spatial distribution of the temperature and/or chemical composition of the process gas flowing through the porous gas distribution device.

According to an embodiment, the gas distribution device 548 can include an open-celled foam. Further, the open-celled foam may be heated using any one of the techniques described above.

The first composition 532 can include one or more constituents of the film forming composition wherein interaction with the gas distribution device 548 is desired. Additionally, the second composition 534 can include one or more constituents of the film forming composition wherein interaction with the gas distribution device 548 is not desired. For example, the first composition 532 can include an initiator and the second composition 534 can include one or more film forming gases. While the one or more film forming gases are introduced to process space 533, the initiator undergoes pyrolysis prior to introduction to process space 533. Once the one or more film forming gases and the initiator radicals interact in process space 533, the initiator radicals can catalyze the dissociation of at least one constituent of the one or more film forming gases.

Referring again to FIG. 1, the power source 50 is configured to provide electrical power to the one or more porous gas distribution elements 55 in the gas distribution system 40. For example, the power source 50 can be configured to deliver either DC power or AC power. Additionally, for example, the power source 50 can be configured to modulate the amplitude of the power, or pulse the power. Furthermore, for example, the power source 50 can be configured to perform at least one of setting, monitoring, adjusting or controlling a power, a voltage, or a current.

Referring still to FIG. 1, a temperature control system 22 can be coupled to the gas distribution system 40, the gas distribution device 45, the process chamber 10 and/or the substrate holder 20, and configured to control the temperature of one or more of these components. The temperature control system 22 can include a temperature measurement system configured to measure the temperature of the gas distribution system 40 at one or more locations, the temperature of the gas distribution device 45 at one or more locations, the temperature of the process chamber 10 at one or more locations and/or the temperature of the substrate holder 20 at one or more locations. The measurements of temperature can be used to adjust or control the temperature at one or more locations in deposition system 1.

The temperature measuring device, utilized by the temperature measurement system, can include an optical fiber thermometer, an optical pyrometer, a band-edge temperature measurement system as described in pending U.S. patent application Ser. No. 10/168544, filed on Jul. 2, 2002, the contents of which are incorporated herein by reference in their entirety, or a thermocouple such as a K-type thermocouple. Examples of optical thermometers include: an optical fiber thermometer commercially available from Advanced Energies, Inc., Model No. OR2000F; an optical fiber thermometer commercially available from Luxtron Corporation, Model No. M600; or an optical fiber thermometer commercially available from Takaoka Electric Mfg., Model No. FT-1420.

Alternatively, when measuring the temperature of one or more resistive heating elements, the electrical characteristics of each resistive heating element can be measured. For example, two or more of the voltage, current or power coupled to the one or more resistive heating elements can be monitored in order to measure the resistance of each resistive heating element. The variations of the element resistance can arise due to variations in temperature of the element which affects the element resistivity.

According to program instructions from the temperature control system 22 or the controller 80 or both, the power source 50 can be configured to operate the gas distribution device 45, e.g., the one or more porous gas distribution elements, at a temperature ranging from approximately 100 degrees C to approximately 600 degrees C. For example, the temperature can range from approximately 200 degrees C to approximately 550 degrees C. The temperature can be selected based upon the film forming composition and, more particularly, the temperature can be selected based upon a constituent of the film forming composition.

Additionally, according to program instructions from the temperature control system 22 or the controller 80 or both, the temperature of the gas distribution system 40 can be set to a value approximately equal to or less than the temperature of the gas distribution device 45, i.e., the one or more heating elements. For example, the temperature can be a value less than or equal to approximately 600 degrees C. Additionally, for example, the temperature can be a value less than approximately 550 degrees C. Further yet, for example, the temperature can range from approximately 80 degrees C to approximately 550 degrees C. The temperature can be selected to be approximately equal to or less than the temperature of the one or more heating elements, and to be sufficiently high to prevent condensation which may or may not cause film formation on surfaces of the gas distribution system and reduce the accumulation of residue.

Additionally yet, according to program instructions from the temperature control system 22 or the controller 80 or both, the temperature of the process chamber 10 can be set to a value less than the temperature of the gas distribution device 45, i.e., the one or more heating elements. For example, the temperature can be a value less than approximately 200 degrees C. Additionally, for example, the temperature can be a value less than approximately 150 degrees C. Further yet, for example, the temperature can range from approximately 80 degrees C to approximately 150 degrees C. However, the temperature may be the same or less than the temperature of the gas distribution system 40. The temperature can be selected to be less than the temperature of the one or more resistive film heating elements, and to be sufficiently high to prevent condensation which may or may not cause film formation on surfaces of the process chamber and reduce the accumulation of residue.

Once film forming composition enters the process space 33, the film forming composition adsorbs on the substrate surface, and film forming reactions proceed to produce a thin film on the substrate 25. According to program instructions from the temperature control system 22 or the controller 80 or both, the substrate holder 20 is configured to set the temperature of substrate 25 to a value less than the temperature of the gas distribution device 45, the temperature of the gas distribution system 40, and the process chamber 10. For example, the substrate temperature can range up to approximately 80 degrees C. Additionally, the substrate temperature can be approximately room temperature. For example, the substrate temperature can range up to approximately 25 degrees C. However, the temperature may be less than or greater than room temperature.

The substrate holder 20 comprises one or more temperature control elements coupled to the temperature control system 22. The temperature control system 22 can include a substrate heating system, or a substrate cooling system, or both. For example, substrate holder 20 can include a substrate heating element or substrate cooling element (not shown) beneath the surface of the substrate holder 20. For instance, the heating system or cooling system can include a re-circulating fluid flow that receives heat from substrate holder 20 and transfers heat to a heat exchanger system (not shown) when cooling, or transfers heat from the heat exchanger system to the substrate holder 20 when heating. The cooling system or heating system may include heating/cooling elements, such as resistive heating elements, or thermoelectric heaters/coolers located within substrate holder 20. Additionally, the heating elements or cooling elements or both can be arranged in more than one separately controlled temperature zone. The substrate holder 20 may have two thermal zones, including an inner zone and an outer zone. The temperatures of the zones may be controlled by heating or cooling the substrate holder thermal zones separately.

Additionally, the substrate holder 20 comprises a substrate clamping system (e.g., electrical or mechanical clamping system) to clamp the substrate 25 to the upper surface of substrate holder 20. For example, substrate holder 20 may include an electrostatic chuck (ESC).

Furthermore, the substrate holder 20 can facilitate the delivery of heat transfer gas to the back-side of substrate 25 via a backside gas supply system to improve the gas-gap thermal conductance between substrate 25 and substrate holder 20. Such a system can be utilized when temperature control of the substrate is required at elevated or reduced temperatures. For example, the backside gas system can comprise a two-zone gas distribution system, wherein the backside gas (e.g., helium) pressure can be independently varied between the center and the edge of substrate 25.

Vacuum pumping system 60 can include a turbo-molecular vacuum pump (TMP) capable of a pumping speed up to approximately 5000 liters per second (and greater) and a gate valve for throttling the chamber pressure. For example, a 1000 to 3000 liter per second TMP can be employed. TMPs can be used for low pressure processing, typically less than approximately 1 Torr. For high pressure processing (i.e., greater than approximately 1 Torr), a mechanical booster pump and dry roughing pump can be used. Furthermore, a device for monitoring chamber pressure (not shown) can be coupled to the process chamber 10. The pressure measuring device can be, for example, a Type 628B Baratron absolute capacitance manometer commercially available from MKS Instruments, Inc. (Andover, Mass.).

Referring still to FIG. 1, the deposition system 1 can further comprise a controller 80 that comprises a microprocessor, memory, and a digital I/O port capable of generating control voltages sufficient to communicate and activate inputs to deposition system 1 as well as monitor outputs from deposition system 1. Moreover, controller 80 can be coupled to and can exchange information with the process chamber 10, the substrate holder 20, the temperature control system 22, the film forming composition supply system 30, the gas distribution system 40, the gas distribution device 45, and the vacuum pumping system 60, as well as the backside gas delivery system (not shown), and/or the electrostatic clamping system (not shown). A program stored in the memory can be utilized to activate the inputs to the aforementioned components of deposition system 1 according to a process recipe in order to perform the method of depositing a thin film.

Controller 80 may be locally located relative to the deposition system 1, or it may be remotely located relative to the deposition system 1 via an internet or intranet. Thus, controller 80 can exchange data with the deposition system 1 using at least one of a direct connection, an intranet, or the internet. Controller 80 may be coupled to an intranet at a customer site (i.e., a device maker, etc.), or coupled to an intranet at a vendor site (i.e., an equipment manufacturer). Furthermore, another computer (i.e., controller, server, etc.) can access controller 80 to exchange data via at least one of a direct connection, an intranet, or the internet.

The deposition system 1 can be periodically cleaned using an in-situ cleaning system (not shown) coupled to, for example, the process chamber 10 or the gas distribution system 40. Per a frequency determined by the operator, the in-situ cleaning system can perform routine cleanings of the deposition system 1 in order to remove accumulated residue on internal surfaces of deposition system 1. The in-situ cleaning system can, for example, comprise a radical generator configured to introduce chemical radical capable of chemically reacting and removing such residue. Additionally, for example, the in-situ cleaning system can, for example, include an ozone generator configured to introduce a partial pressure of ozone. For instance, the radical generator can include an upstream plasma source configured to generate oxygen or fluorine radical from oxygen (O₂), nitrogen trifluoride (NF₃), O₃, XeF₂, ClF₃, or C₃F₈ (or, more generally, CₓF_{y}), respectively. The radical generator can include an ASTRON® reactive gas generator, commercially available from MKS Instruments, Inc., ASTeX® Products (90 Industrial Way, Wilmington, Mass. 01887).

Although the porous gas distribution device has been described for use in a deposition system, the porous gas distribution device may be used in any system requiring gas heating. Other systems in semiconductor manufacturing and integrated circuit (IC) manufacturing may include etching systems, thermal processing systems, etc.

FIG. 9 illustrates a method of depositing a thin film on a substrate according to another embodiment. The method 800 includes, at 810, coupling a gas heating device to a process chamber for a deposition system, wherein the gas heating device comprises one or more porous gas distribution elements configured to receive an electrical current from one or more power sources. For example, the one or more porous gas distribution elements may comprise an open-celled foam.

In 820, a temperature of the gas heating device is elevated. For example, the temperature may be elevated by flowing electrical current to or through the porous gas distribution element as described above.

In 830, a substrate is provided in the process chamber of the deposition system. For example, the deposition system can include the deposition system described above in FIG. 1. The substrate can, for example, be a Si substrate. A Si substrate can be of n- or p-type, depending on the type of device being formed. The substrate can be of any size, for example a 200 mm substrate, a 300 mm substrate, or an even larger substrate. According to an embodiment of the invention, the substrate can be a patterned substrate containing one or more vias or trenches, or combinations thereof.

In 840, a film forming composition is provided to a gas distribution system that is configured to introduce the film forming composition to the process chamber above the substrate. For example, the gas distribution system can be located above the substrate and opposing an upper surface of the substrate.

In 850, one or more constituents of the film forming composition are subjected to pyrolysis using the gas heating device. The gas heating device can be any one of the systems described in FIGS. 2 through 8 above, or any combination thereof.

In 860, the substrate is exposed to the film forming composition to facilitate the formation of the thin film. The temperature of the substrate can be set to a value less than the temperature of the one or more heating elements, e.g. one or more resistive film heating elements. For example, the temperature of the substrate can be approximately room temperature.

The method may further comprise adjusting a first flow of the film forming composition through one of the one or more porous gas distribution elements relative to a second flow of the film forming composition through another of the one or more porous gas distribution elements. Additionally, the method may further comprise adjusting a first temperature of one of the one or more porous gas distribution elements relative to a second temperature of another of the one or more porous gas distribution elements.

Although only certain embodiments of this invention have been described in detail above, those skilled in the art will readily appreciate that many modifications are possible in the embodiments without materially departing from the novel teachings and advantages of this invention. Accordingly, all such modifications are intended to be included within the scope of this invention.

1. A gas distribution device, comprising:
one or more porous gas distribution elements configured to be heated and pyrolize a process gas flowing through said one or more porous gas distribution elements.

2. The gas distribution device of claim 1, wherein one of said one or more porous gas distribution elements comprises an open-celled foam.

3. The gas distribution device of claim 2, wherein the density of said open-celled foam ranges from approximately 3% to approximately 60% the density of the solid base material of said open-celled foam.

4. The gas distribution device of claim 2, wherein the density of said open-celled foam ranges from approximately 20% to approximately 40% the density of the solid base material of said open-celled foam.

5. The gas distribution device of claim 2, wherein the pore density of said open-celled foam ranges from approximately 5 pores per linear inch to approximately 60 pores per linear inch.

6. The gas distribution device of claim 2, wherein said open-celled foam comprises a metal-containing foam, a metal foam, or a metal alloy foam.

7. The gas distribution device of claim 2, wherein said open-celled foam comprises a non-metal foam.

8. The gas distribution device of claim 2, wherein said open-celled foam comprises a non-metal foam coated with metal-containing material.

9. The gas distribution device of claim 8, wherein said metal-containing material is vapor deposited on said non-metal foam.

10. The gas distribution device of claim 1, wherein said one or more porous gas distribution elements is configured to receive an electrical current from one or more power sources, and wherein said one or more power sources comprises a direct current (DC) power source or an alternating current (AC) power source.

11. The gas distribution device of claim 10, wherein one of said one or more porous gas distribution elements comprises an open-celled foam, and wherein said one or more power sources couples electrical current directly to said open-celled foam.

12. The gas distribution device of claim 10, wherein one of said one or more porous gas distribution elements comprises:
an open-celled foam; and
one or more electrodes coupled to said open-celled foam,
wherein at least one of said one or more electrodes is coupled to said one or more power sources, and wherein at least one of said one or more electrodes is coupled to electrical ground for said one or more power sources.

13. The gas distribution device of claim 12, wherein a first electrode is located at a top surface of said open-celled foam and a second electrode is located at a bottom surface of said open-celled foam, and wherein a voltage difference is applied across said first electrode and said second electrode to cause said flow of electrical current through said open-celled foam.

14. The gas distribution device of claim 1, wherein one of said porous gas distribution element comprises:
an open-celled foam; and
a resistive heating element coupled to said open-celled foam and configured to heat said open-celled foam when said electrical current from said one or more power sources flows through said resistive heating element.

15. The gas distribution device of claim 1, wherein said one or more porous gas distribution elements are configured to receive and distribute a film forming composition in a deposition system for depositing a film on a substrate, and wherein said one or more porous gas distribution elements are configured to cause pyrolysis of one or more constituents of said film forming composition.

16. The gas distribution device of claim 1, wherein said one or more porous gas distribution elements comprise a porous gas distribution plate formed of an open-celled foam.

17. A gas distribution device, comprising:
a temperature control element; and
one or more porous gas distribution elements coupled to a temperature control element and configured to be temperature-controlled and distribute a process gas flowing through said one or more porous gas distribution elements,
wherein said one or more porous gas distribution elements comprises an open-celled foam.

18. A method of depositing a thin film on a substrate, the method comprising:
coupling a gas heating device to a process chamber, said gas heating device comprising one or more porous gas distribution elements configured to receive an electrical current from one or more power sources;
elevating a temperature of said gas heating device by coupling said electrical current from said one or more power sources to said porous gas heating device;
providing a substrate on a substrate holder in said process chamber of a deposition system;
providing a film forming composition to a gas distribution system located above said substrate and opposing an upper surface of said substrate;
pyrolizing one or more constituents of said film forming composition using said porous gas heating device; and
exposing said substrate to said film forming composition in said process chamber.

19. The method of claim 18, further comprising:
adjusting a first flow of said film forming composition through one of said one or more porous gas distribution elements relative to a second flow of said film forming composition through another of said one or more porous gas distribution elements.

20. The method of claim 18, further comprising:
adjusting a first temperature of one of said one or more porous gas distribution elements relative to a second temperature of another of said one or more porous gas distribution elements.
